(19) United States
(12) Patent Application Publication
(10) Pub. No.: US 2018/0217509 A1
(43) Pub. Date: Aug. 2, 2018

(54) METHOD AND DEVICE FOR CHARACTERIZING A WAFER PATTERNED BY AT LEAST ONE LITHOGRAPHY STEP

(71) Applicant: Carl Zeiss SMT GmbH, Oberkochen (DE)

(72) Inventor: Hans-Michael Stiepan, Aalen (DE)

(21) Appl. No.: 15/937,014

(22) Filed: Mar. 27, 2018

Related U.S. Application Data
(63) Continuation of application No. PCT/EP2016/075640, filed on Oct. 25, 2016.

(30) Foreign Application Priority Data
Nov. 5, 2015 (DE) 10 2015 221 773.6

(51) Int. Cl. G03F 7/20; G01N 21/95; G01B 11/02; G01B 11/27; G01N 21/88

(52) U.S. Cl. CPC G03F 7/70633; G03F 7/70625; G03F 7/70508; G03F 7/705; G01N 2201/0683; G01B 11/02; G01B 11/272; G01N 21/8806; G01N 2021/8848; G01N 21/9501

(57) ABSTRACT

A method includes determining at least one characteristic variable which is characteristic of a patterned wafer based on a plurality of measurements of the intensity of electromagnetic radiation after the diffraction thereof at the patterned wafer. The intensity measurements are carried out for at least two different orders of diffraction. For at least two regions on the wafer, in each case a value of the characteristic variable that is assigned to the respective region is determined on the basis of a comparison of the measurement values obtained in the intensity measurements for the at least two orders of diffraction. The intensity measurements for determining the characteristic variable for the at least two regions on the wafer are carried out simultaneously.

### CROSS-REFERENCE TO RELATED APPLICATIONS

The present application is a continuation of, and claims benefit under 35 USC 120 to, international application PCT/EP2016/075640, filed Oct. 25, 2016, which claims benefit under 35 USC 119 of German Application No. 10 2015 221 773.6, filed on Nov. 5, 2015. The entire disclosure of these applications are incorporated by reference herein.

### FIELD

The disclosure relates to a method and a device for characterizing a wafer patterned by at least one lithography step.

### BACKGROUND

Microlithography is used for producing microstructured components, such as for example integrated circuits or LCDs. The microlithography process is carried out in what is called a projection exposure apparatus, which includes an illumination device and a projection lens. The image of a mask (=reticle) illuminated by way of the illumination device is in this case projected by way of the projection lens onto a substrate (e.g. a silicon wafer) coated with a light-sensitive layer (photoresist) and arranged in the image plane of the projection lens, in order to transfer the mask structure to the light-sensitive coating of the substrate.

In this case, in practice there is often a desire to monitor the relative position of structures produced on the wafer in different lithography steps, the highest possible accuracies (e.g. of the order of magnitude of 1 nm) being striven for. This is the case e.g. when monitoring the overlay accuracy in so-called “multi-patterning” methods, which involve producing the structures on the wafer for undershooting the resolution limit of the optical system in a plurality of lithography steps.

When monitoring the relative position of structures or the overlay accuracy, it is also known, inter alia, to produce marker regions or marker structures in particular in edge regions of the wafer elements respectively produced, in order to carry out a diffraction-based overlay determination in a scatterometric set-up on the basis of the marker regions or marker structures. In this case, however, in practice the problem occurs that, on account of the multiplicity of marker structures to be measured, the relevant overlay determination and also, if appropriate, the determination of further relevant characteristic variables which are characteristic of the patterned wafer are time-consuming, and hence the achievable throughput of the lithography method is adversely affected as a result.

In respect of the prior art, reference is made merely by way of example to US 2006/0274325 A1, U.S. Pat. No. 8,339,595 B2, U.S. Pat. No. 8,670,118 B2 and US 2012/0224176 A1.

### SUMMARY

The present disclosure seeks to provide a method and a device for characterizing a wafer patterned by at least one lithography step which enable one or more characteristic variables which are characteristic of the patterned wafer, in particular the relative position of structures produced in different lithography steps on the wafer, to be determined with the least possible impairment of the throughput of the projection exposure apparatus.

In one aspect, the disclosure provides a method for characterizing a wafer patterned by at least one lithography step. At least one characteristic variable which is characteristic of the patterned wafer is determined on the basis of a plurality of measurements of the intensity of electromagnetic radiation after the diffraction thereof at the patterned wafer. These intensity measurements are carried out for at least two different orders of diffraction. For at least two regions on the wafer, in each case a value of the characteristic variable that is assigned to the respective region is determined on the basis of a comparison of the measurement values obtained in the intensity measurements for the at least two orders of diffraction. The intensity measurements for determining the characteristic variable for the at least two regions on the wafer are carried out simultaneously.

In one aspect, the disclosure provides a device for characterizing a wafer patterned by at least one lithography step. At least one characteristic variable which is characteristic of the patterned wafer is determinable on the basis of a plurality of measurements of the intensity of electromagnetic radiation after the diffraction thereof at the patterned wafer. The device is configured to carry out a method as described herein.

In a method according to the disclosure for characterizing a wafer patterned by at least one lithography step, wherein at least one characteristic variable which is characteristic of the patterned wafer is determined on the basis of a plurality of measurements of the intensity of electromagnetic radiation after the diffraction thereof at the patterned wafer, these intensity measurements are carried out for at least two different orders of diffraction, wherein for at least two regions on the wafer, in each case a value of the characteristic variable that is assigned to the respective region is determined on the basis of a comparison of the measurement values obtained in the intensity measurements for the at least two orders of diffraction, and wherein the intensity measurements for determining the characteristic variable for the at least two regions on the wafer are carried out simultaneously.

The disclosure is based firstly on the principle, by carrying out a diffraction-based measurement for at least two different orders of diffraction, of also enabling the determination of the relative position of structures produced in different lithography steps on the wafer with respect to one another, thereby taking account of the circumstance that a diffraction-based measurement for instance solely in the zero order of diffraction would be insufficient for this purpose for reasons of symmetry.

Proceeding from this principle, the disclosure is then based on the concept, in particular, of carrying out such a diffraction-based intensity measurement not just for one region on the wafer or in order to obtain a single overlay value for a specific measurement time or measurement step, but rather of correspondingly measuring simultaneously a plurality of regions (i.e. at least two regions, but in principle as many regions as desired) on the wafer and of determining all at once a corresponding number of characteristic variables or overlay values which are respectively assigned to the regions. The regions on the wafer can be either marker regions or marker structures which are provided specifically for this purpose (and otherwise have no function) or else used structures on the wafer.

As a result, a considerable speed advantage is achieved according to the disclosure, such that even a measurement of a multiplicity of marker structures or determination of a multiplicity of (e.g. marker) structures that is used for characterizing complex used structures is made possible without the throughput of the projection exposure apparatus being impaired to an excessively great extent.

The disclosure is not restricted to solely determining overlay values, but rather makes it possible at the same time to determine further relevant parameters such as e.g. line widths (CD value), layer thicknesses, etc.

In accordance with one embodiment, the intensity measurements are carried out for different wavelengths.

In accordance with one embodiment, the intensity measurements are carried out for different polarization states of the electromagnetic radiation.

In accordance with one embodiment, the characteristic variable is determined on the basis of a comparison of measurement values obtained on the basis of the intensity measurements for the at least two orders of diffraction with values simulated in a model-based manner. This comparison can be carried out iteratively, in particular.

In accordance with one embodiment, the orders of diffraction for which the intensity measurements are carried out include the +1st order of diffraction and the −1st order of diffraction.

In accordance with one embodiment, the orders of diffraction for which the intensity measurements are carried out include the 0 order of diffraction.

In accordance with one embodiment, the at least one characteristic variable determined describes the relative position of two structures produced on the wafer, in particular of two structures produced on the wafer in different lithography steps, with respect to one another.

In accordance with one embodiment, the at least one characteristic variable determined describes the overlay accuracy of two structures produced in different lithography steps.

In accordance with one embodiment, the at least one characteristic variable determined describes a CD value.

In accordance with one embodiment, the electromagnetic radiation impinges on the wafer with a maximum numerical aperture of less than 0.1, in particular less than 0.05, more particularly less than 0.01.

In accordance with one embodiment, the intensity measurements are carried out with at least one detector, wherein each of the at least two regions on the wafer is assigned to a respective region on the detector.

In accordance with one embodiment, the electromagnetic radiation impinges on the detector with a maximum numerical aperture of less than 0.1, in particular less than 0.05, more particularly less than 0.01.

In accordance with one embodiment, the at least one detector is embodied in a pivotable fashion. In this way, it is possible to take account of a variation of the direction of the electromagnetic radiation respectively diffracted at the wafer structures for different wavelengths, different grating periods of the respective structures and also different orders of diffraction by virtue of the fact that the light possibly diffracted in these directions can also be captured via a pivoting movement of the detector.

In accordance with one embodiment, the at least one detector is embodied as a linear camera including a linear array of camera sensors. In this case, the wafer can be respectively correspondingly tilted and moved back and forth. This configuration has the advantage of the optically simpler optical correction for a line in comparison with a field, such that a comparatively compact set-up can be achieved.

In accordance with one embodiment, the at least two regions on the wafer correspond to an integral area of at least 1 mm², in particular of at least 10 mm², more particularly of at least 100 mm².

In accordance with one embodiment, a variation of the diffraction direction of the electromagnetic radiation, the variation occurring depending on the wavelength, is at least partly compensated for by the use of at least one grating in the optical beam path.

In accordance with one embodiment, the electromagnetic radiation is reflected back after the diffraction thereof at the patterned wafer by the use of a Littrow grating. As a result, e.g. the light diffracted in the +1st or −1st order of diffraction can in each case be reflected back on itself, as a result of which a more compact set-up can be realized overall with regard to the detector arrangement.

The disclosure furthermore relates to a device for characterizing a wafer patterned by at least one lithography step, wherein at least one characteristic variable which is characteristic of the patterned wafer is determinable on the basis of a plurality of measurements of the intensity of electromagnetic radiation after the diffraction thereof at the patterned wafer, wherein the device is configured to carry out a method having the features described above. With regard to advantages and advantageous configurations of the device, reference is made to the above explanations in association with the method according to the disclosure.

Further configurations of the disclosure can be gathered from the description and the dependent claims.

### BRIEF DESCRIPTION OF THE DRAWINGS

The disclosure is explained in greater detail below on the basis of exemplary embodiments illustrated in the accompanying figures, in which:

FIG. 1 shows a schematic illustration of a possible set-up of a measuring arrangement or device for carrying out the method according to the disclosure;

FIG. 2 shows a schematic illustration for elucidating the overlay value determined according to the disclosure;

FIGS. 3A-3B show schematic illustrations for elucidating the calculation according to the disclosure of overlay values and, if appropriate, further characteristic variables from the intensity values obtained using the measuring arrangement from FIG. 1; and

FIGS. 4-9 show schematic illustrations of the possible set-up of a measuring arrangement or device for carrying out the method according to the disclosure in further embodiments.

### DETAILED DESCRIPTION OF PREFERRED EMBODIMENTS

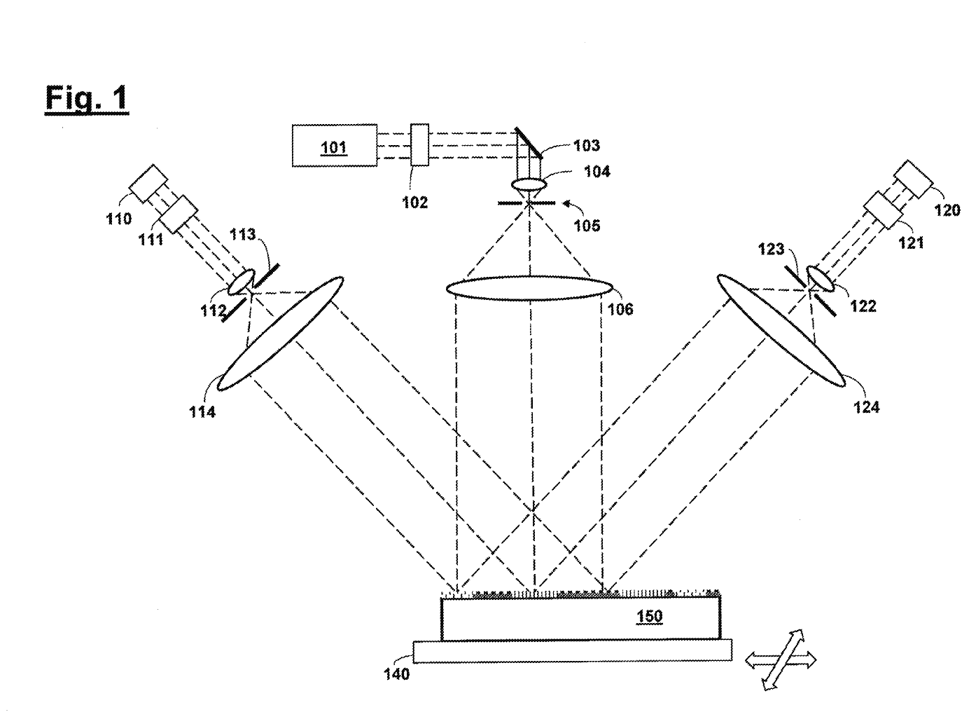

FIG. 1 firstly shows, in a schematic illustration, the possible set-up of a measuring arrangement or device for carrying out the method according to the disclosure.

The measuring arrangement in FIG. 1 is configured as a scatterometer and includes a light source 101, which can be e.g. a broadband tunable light source for generating a wavelength spectrum (for example in the wavelength range of 300 nm to 800 nm). The light from the light source 101, via a polarizer 102 (possibly exchangeable in order to set linearly polarized light having different polarization directions), a deflection mirror 103, a lens element 104, a stop 105 and a further lens element 106, impinges on a wafer 150 arranged on a wafer plane or wafer stage 140, or impinges on the structures (merely indicated schematically in FIG. 1) that have already been produced lithographically on the wafer 150.

After diffraction at the structures, the light in accordance with FIG. 1 passes in the −1st order of diffraction (illustrated on the left in FIG. 1) via a lens element 114, a stop 113, a further lens element 112 and an analyzer 111 onto a first detector (camera) 110. In the +1st order of diffraction (illustrated on the right in FIG. 1) the light passes via a lens element 124, a stop 123, a further lens element 122 and an analyzer 121 onto a second detector (camera) 120. With the use of the tunable light source 101 or polarizers 102, the intensity measurement can be effected by the detectors 110, 120 for a multiplicity of different wavelengths or polarization states. In further embodiments, other orders of diffraction can also be taken into account in addition or as an alternative to the ±1st order of diffraction.

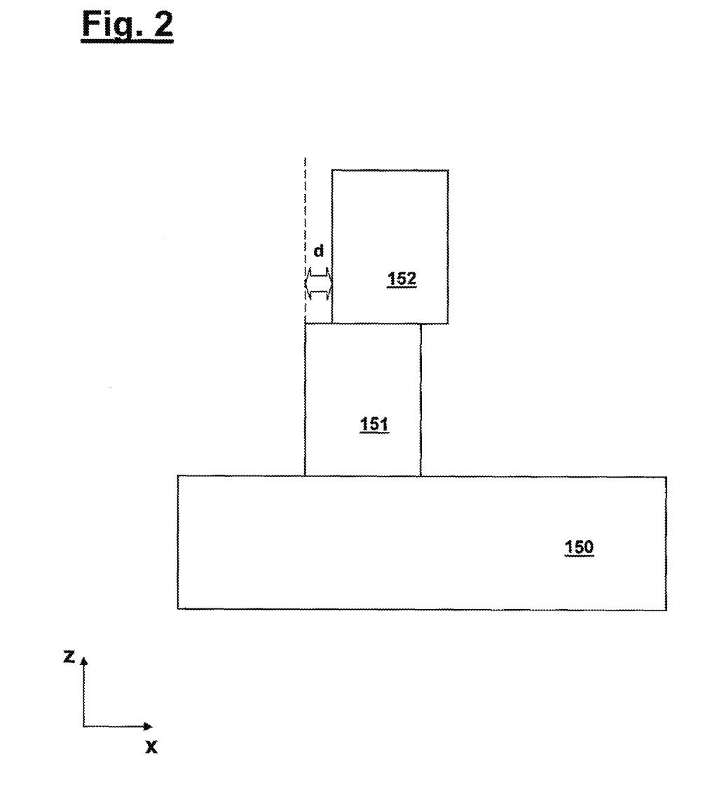

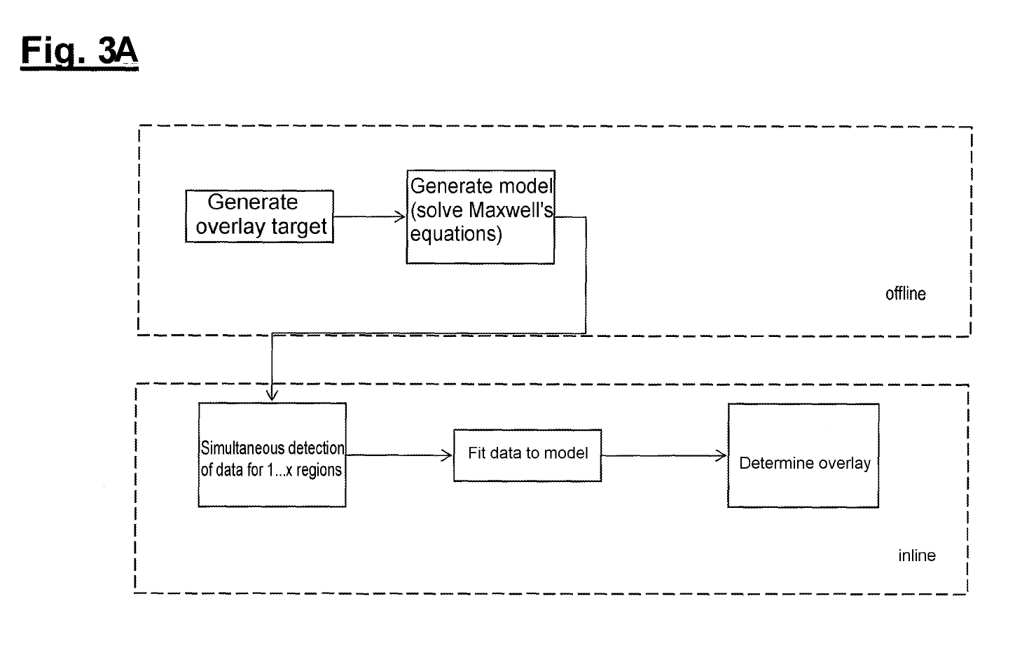

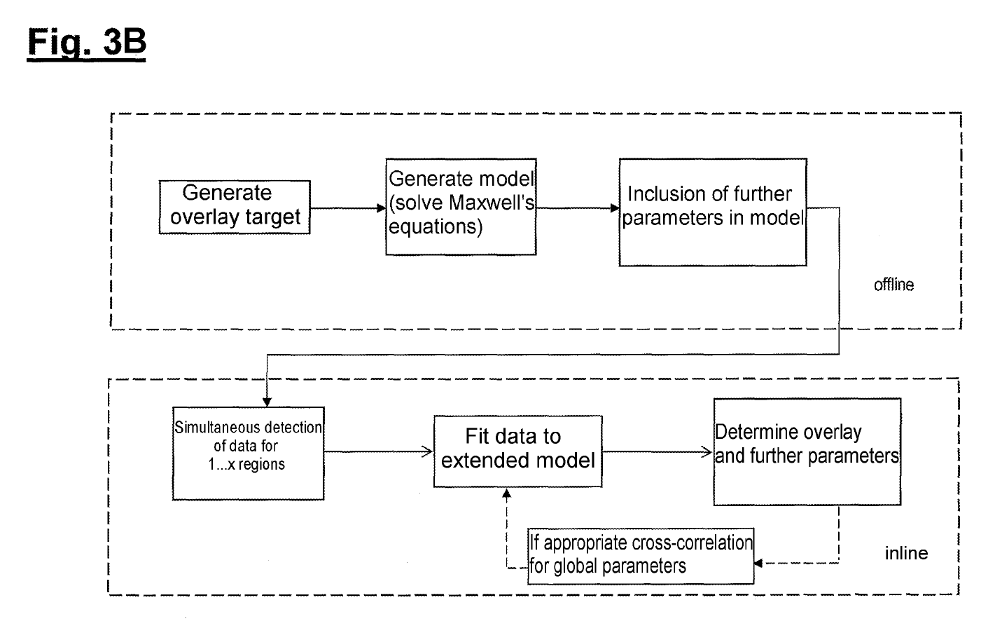

On the basis of the intensity values respectively measured by the detectors 110, 120, via comparison (in particular difference formation), a determination or monitoring of the relative position of structures produced in different lithography steps on the wafer 150 (e.g. marker structures provided for this purpose) can be performed in principle in a model-based fashion in accordance with the methods illustrated in FIG. 3A (for the example of overlay determination) and FIG. 3B (for the overlay determination and additional determination of further parameters or characteristic variables), in a manner known per se. FIG. 2 indicates merely schematically two structures produced in different lithography steps on the wafer 150, the structures having an offset d, which is determinable according to the disclosure, in the lateral direction (x-direction in the coordinate system depicted).

For the overlay determination mentioned above, the measurement values obtained for different combinations of polarization, order of diffraction and wavelength (e.g. 2*2*10=40 measurement values in the case of measurement for two different polarization states, two orders of diffraction and ten different wavelengths) in accordance with FIG. 3A and FIG. 3B are respectively fitted to a model generated by solving Maxwell's equations, wherein e.g. the least square deviation method can be applied. In this case, if appropriate, an iteration can also be carried out, as indicated in FIG. 3B.

In view of the possibly large number of characteristic variables to be determined in the case of used structures, if desired additional parameters such as CD can furthermore be determined. Furthermore, it is also possible, during the determination of the overlay, to include values for specific critical parameters that were obtained by measuring other marker or used structures. This is based on the fact that e.g. the value of a flank angle in one structure is strongly correlated with the value of a flank angle in another structure.

According to the disclosure, then, the above-described determination of the overlay value respectively assigned to a patterned wafer region and, if appropriate, of further parameters or characteristic variables (e.g. CD value) at each measurement time or in each measurement step is effected not just for a single patterned wafer region, but rather simultaneously for a plurality of wafer regions, i.e. for determining a plurality of overlay values or further characteristic variables, wherein each of the overlay values is respectively assigned to one of the plurality of regions being measured simultaneously. This is made possible in the measuring arrangement from FIG. 1 in particular by virtue of the fact that the light impinges both on the wafer 150 and on the respective detector 110 or 120 in a substantially collimated beam path, wherein each of the patterned wafer regions mentioned above corresponds to a (camera) region imaged onto the respective detector 110 or 120.

Accordingly, according to the disclosure, in each measurement step or at each measurement time, not just individual spots (for determining in each case only a single overlay value) are measured, rather a field is imaged on the relevant detector (camera) 110 or 120. In this case, the field imaged according to the disclosure can have a size of typically a plurality of mm². In this case, merely by way of example, the simultaneously recorded overall region on the wafer can correspond to the size of a typical wafer element or chip (“die”) and have a value of e.g. 26 mm*33 mm.

The disclosure is not restricted further with regard to the constitution of the individual wafer regions measured simultaneously as described above. In this regard, the structures present on the wafer regions can be different or else identical structures, used structures or otherwise functionless marker structures. Furthermore, regions of one and the same continuous periodic structure can also be involved, for which then overlay values are thus determined according to the disclosure at different locations on the wafer.

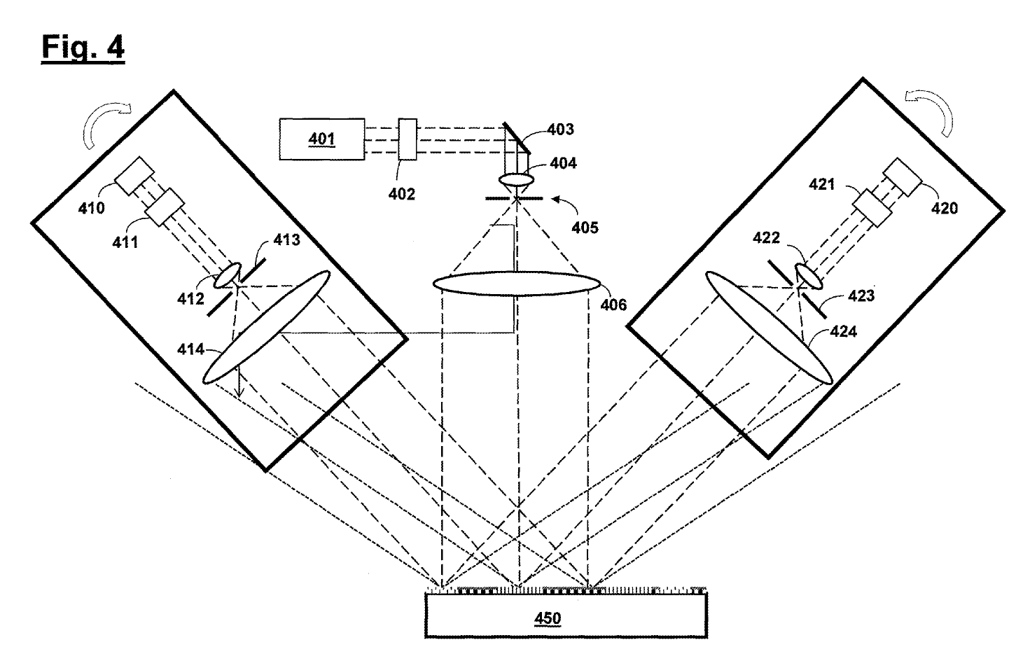

FIG. 4 shows, in a schematic illustration, a further possible embodiment of a measuring arrangement according to the disclosure, wherein components analogous or substantially functionally identical to FIG. 1 are designated by reference numerals increased by “300”.

The measuring arrangement in FIG. 4 differs from that from FIG. 1 merely in that the sections including the respective detector 410 and 420 and also the components 411-414 and 421-424, respectively, are embodied in a pivotable fashion in order to take account of a variation of the direction of the electromagnetic radiation respectively diffracted at the wafer structures for different wavelengths, different grating periods of the respective structures and also different orders of diffraction and thus also to capture the light possibly diffracted in these directions.

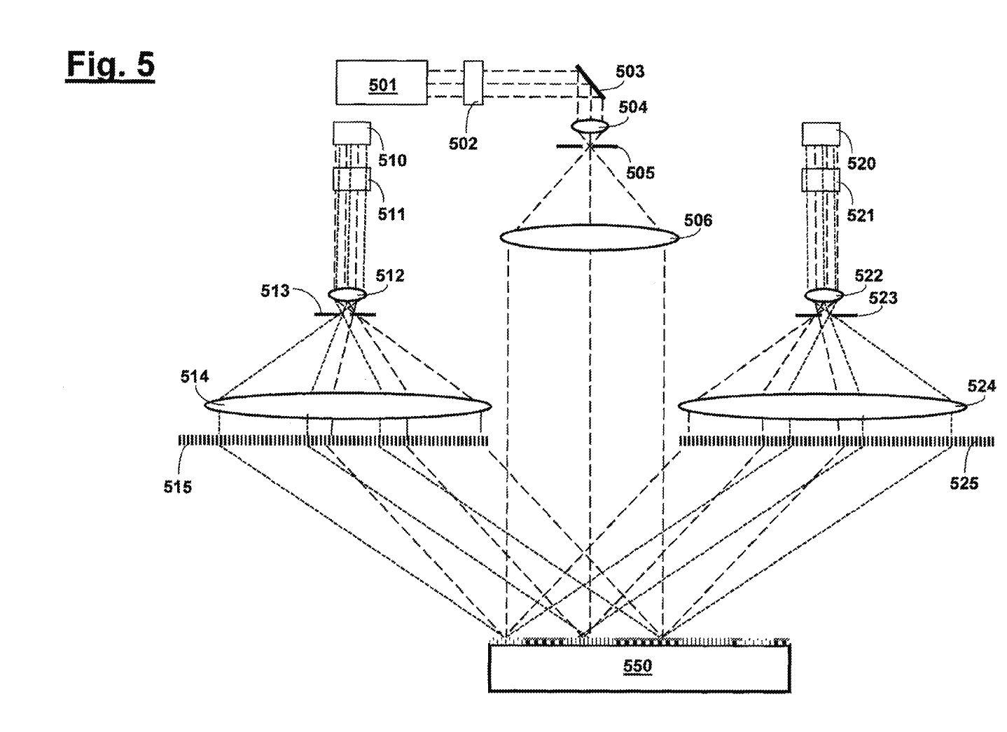

FIG. 5 shows a further embodiment of a measuring arrangement, wherein components analogous or substantially functionally identical to FIG. 4 are designated by reference numerals increased by “100”.

In accordance with FIG. 5, the abovementioned effect of the variation of the diffraction direction depending on the wavelength is compensated for by the use of a respective grating 515 and 525 (operated in transmission) configured to be arranged in the beam path downstream of the wafer 550 (wherein the gratings 515 and 525 are correspondingly fabricated in order to achieve the desired compensation effect).

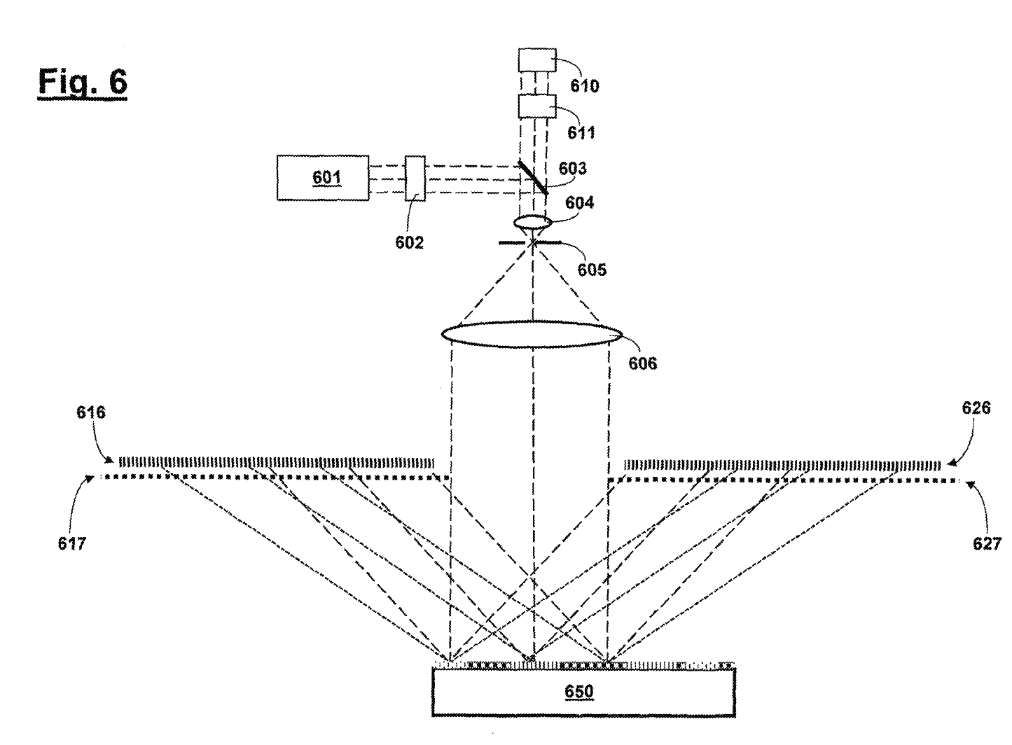

FIG. 6 shows a further possible embodiment of a measuring arrangement according to the disclosure, wherein components analogous or substantially functionally identical to FIG. 5 are designated by reference numerals increased by “100”.

In accordance with FIG. 6, a more compact set-up of the measuring arrangement is realized by virtue of the fact that for the +1st and −1st orders of diffraction, use is made of Littrow gratings 616 and 626 respectively (each with an associated stop arrangement (shutter) 617 and 627 arranged upstream thereof in the light propagation direction). As a result, the light diffracted in the +1st and −1st orders of diffraction is in each case reflected back on itself, such that a more compact set-up can be realized overall with regard to the detector arrangement.

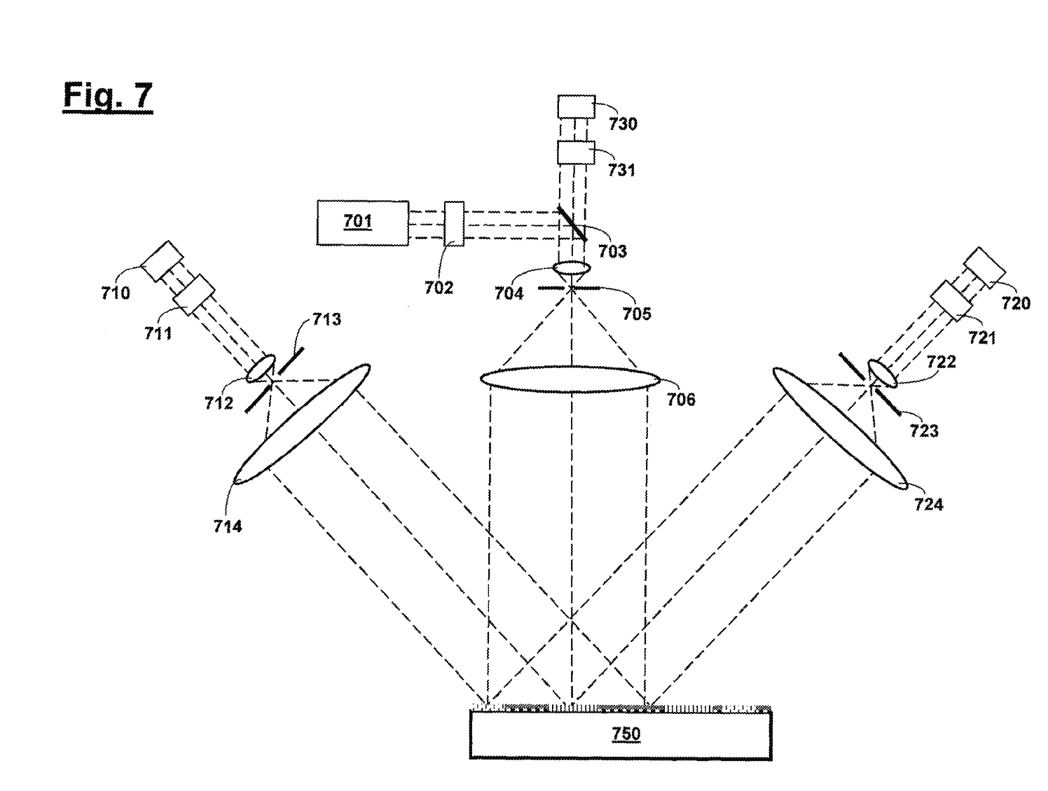

FIG. 7 shows a further embodiment of a measuring arrangement according to the disclosure, wherein components analogous or substantially functionally identical to FIG. 1 are designated by reference numerals increased by “600”.

The measuring arrangement in accordance with FIG. 7 differs from that in accordance with FIG. 1 in that the measuring arrangement in accordance with FIG. 7—in addition to the detection of the light diffracted in the +1st and −1st orders of diffraction—is also configured for detecting the light emanating from the wafer 750 in the zero order of diffraction and a further detector (camera) 730 with an analyzer 731 arranged upstream thereof in the light propagation direction is provided for this purpose.

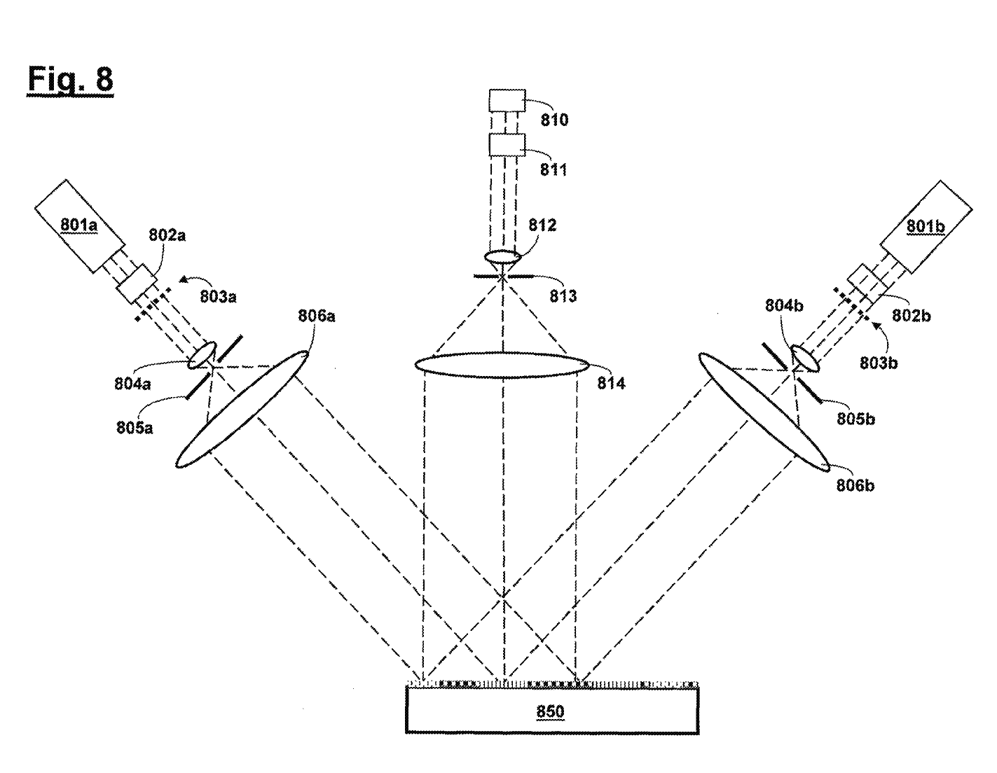

FIG. 8 shows a further embodiment of a measuring arrangement, wherein components analogous or substantially functionally identical to FIG. 1 are designated by reference numerals increased by “700”.

In accordance with FIG. 8, the measuring arrangement includes an inverted set-up in comparison with FIG. 1, for instance, insofar as in accordance with FIG. 8 two “illumination units” each having a light source 801a and 801b respectively (followed by the other components 802a-806a and 802b-806b respectively) are provided, such that only one detector (camera) 810 with the corresponding components 811-814 is involved here.

The detector 810 detects the +1st order of diffraction for the light coming from the first light source 801a, whereas it detects the −1st order of diffraction for light coming from the second light source 801b (or vice versa). As a result, firstly the optical set-up can be simplified and secondly, on account of the typically more cost-effective illumination components in comparison with the detector 810, if appropriate a cost advantage can also be achieved.

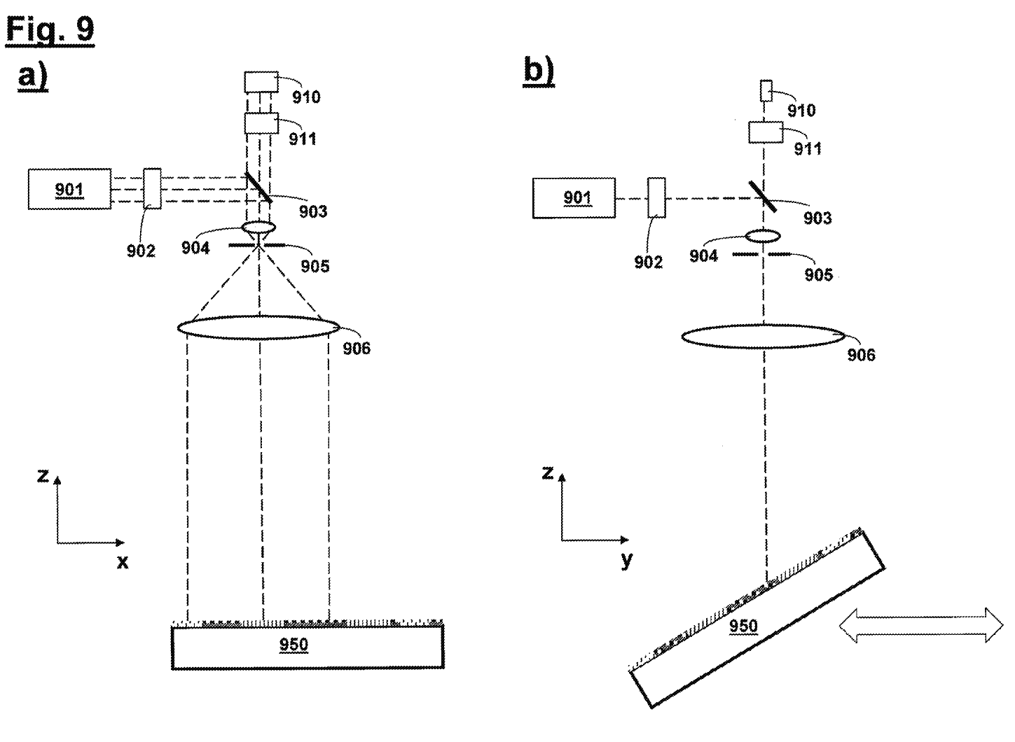

FIGS. 9a-b show a further possible configuration of a measuring arrangement, wherein components analogous or substantially functionally identical to FIG. 1 are designated by reference numerals increased by “800”.

In accordance with FIGS. 9a-b, the intensity measurement according to the disclosure is effected using a detector 910 including a linear sensor array (“linescan camera”=linear camera), wherein here the wafer 950 is correspondingly tilted and moved back and forth, as indicated in FIG. 9b. This configuration has the advantage of the optically simpler optical correction for a line in comparison with a field, such that a comparatively compact set-up can be achieved here, too.

In further embodiments, the measuring arrangement according to the disclosure e.g. proceeding from FIG. 1 or FIG. 4 can also include four instead of only two detector branches or arms in order to determine the overlay values respectively determined in two mutually perpendicular directions (x- and y-directions).

In the embodiments described above, the detectors 110, 120, . . . can each be configured as individually tiltable.

In a further embodiment (e.g. proceeding once again from FIG. 1) the measuring arrangement can also be configured in such a way that the detectors 110 and 120, with the use of discrete wavelengths, capture precisely the +1st and

−1st orders of diffraction respectively for a first wavelength (e.g. 800 nm), precisely the

+2nd and −2nd orders of diffraction respectively for a second wavelength (of e.g. 400 nm) and the +3rd and −3rd orders of diffraction for a third wavelength (of e.g. 200 nm). In this way, the desire for a pivotable embodiment of the respective detector branches or arms can be avoided, if appropriate.

Even though the disclosure has been described on the basis of specific embodiments, numerous variations and alternative embodiments are apparent to a person skilled in the art, for example by combination and/or exchange of features of individual embodiments. Accordingly, it goes without saying for the person skilled in the art that such variations and alternative embodiments are concomitantly encompassed by the present disclosure, and the scope of the disclosure is restricted only within the meaning of the appended patent claims and the equivalents thereof.

What is claimed is:

1. A method, comprising:
determining a variable which is characteristic of a patterned wafer based on a plurality of measurements of the intensity of electromagnetic radiation after the electromagnetic radiation diffracts from the patterned wafer,
wherein:
the intensity measurements are carried out for at least two different orders of diffraction;
for each of at least two regions on the wafer, a value of the variable that is assigned to the region is determined based on a comparison of the measured intensity values for the at least two orders of diffraction; and
the measured intensity values are simultaneously measured for the at least two regions on the wafer.

2. The method of claim 1, comprising performing the intensity measurements for different wavelengths of the electromagnetic radiation.

3. The method of claim 1, comprising performing the intensity measurements for different polarization states of the electromagnetic radiation.

4. The method of claim 1, comprising determining the variable based on a comparison of measurement values obtained based on the intensity measurements for the at least two orders of diffraction with values simulated in a model-based manner.

5. The method of claim 4, further comprising iteratively performing the comparison.

6. The method of claim 1, wherein the at least two orders of diffraction comprise the +1st order of diffraction and the −1st order of diffraction.

7. The method of claim 6, wherein the at least two orders of diffraction comprise the 0 order of diffraction.

8. The method of claim 1, wherein the at least two orders of diffraction comprise the 0 order of diffraction.

9. The method of claim 1, wherein the variable describes a relative position of two structures on the wafer.

10. The method of claim 1, wherein the variable describes a relative position of two structures on the wafer produced on the wafer in different lithography steps.

11. The method of claim 1, wherein the variable describes an overlay accuracy of two structures on the wafer produced in different lithography steps.

12. The method of claim 1, wherein the variable describes a CD value.

13. The method of claim 1, wherein the electromagnetic radiation impinges on the wafer with a maximum numerical aperture of less than 0.1.

14. The method of claim 1, comprising performing the intensity measurements with a detector, wherein each of the at least two regions on the wafer is assigned to a respective region on the detector.

15. The method of claim 14, wherein the electromagnetic radiation impinges on the detector with a maximum numerical aperture of less than 0.1.

16. The method of claim 14, wherein the detector is pivotable.

17. The method of claim 14, wherein the detector comprises a linear camera comprising a linear array of camera sensors.

18. The method of claim 1, wherein the at least two regions on the wafer correspond to an integral area of at least 1 mm².

19. The method of claim 1, further comprising using a grating in the optical beam path to at least partly compensate for a variation of the diffraction direction of the electro-magnetic radiation which depends on the wavelength of the electromagnetic radiation.

20. The method of claim 1, further comprising using a Littrow grating to reflect back the electromagnetic radiation after the diffraction thereof at the patterned wafer.
